(19) United States
(12) Patent Application Publication
(10) Pub. No.: US 2009/0166873 A1
(43) Pub. Date: Jul. 2, 2009

(54) INTER-CONNECTING STRUCTURE FOR SEMICONDUCTOR DEVICE PACKAGE AND METHOD OF THE SAME

(75) Inventors: Wen-Kun Yang, Hsin-Chu City (TW); Jui-Hsien Chang, Jhudong Township (TW); Chi-Chen Lee, Taipei City (TW); Mon-Chin Tsai, Chung-Tong Town (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/965,157

(22) Filed: Dec. 27, 2007

(51) Int. Cl. H01L 23/498; H01L 21/60

(52) U.S. Cl. 257/758; 257/774; 438/118; 257/E23.067; 257/E21.511

(57) ABSTRACT

The interconnecting structure for a semiconductor die includes a die having bonding pads on an active surface; a core attached the side wall (edge) of the die by adhesion material; an isolating base adhered on the active surface of the die by adhesion glue; a through silicon via (TSV) open from the back side of the die to expose the bonding pads; a build up layer coupled between the bonding pads to terminal metal pads by the through silicon via; solder balls melted on terminal pads, wherein the terminal pads located on the core and/or the die.

### FIELD OF THE INVENTION

This invention relates to a semiconductor device package, and more particularly to an inter-connecting structure of package.

### BACKGROUND OF THE INVENTION

The function of chip package includes power distribution, signal distribution, heat dissipation, protection and support. As a semiconductor become more complicated, the traditional package technique, for example lead frame package, flex package, rigid package technique, can't meet the demand of producing smaller chip with high density elements on the chip. In general, array packaging such as Ball Grid Array (BGA) packages provide a high density of interconnects relative to the surface area of the package. Typical BGA packages include a convoluted signal path, giving rise to high impedance and an inefficient thermal path which results in poor thermal dissipation performance. With increasing package density, the spreading of heat generated by the device is increasingly important. In order to meet packaging requirements for newer generations of electronic products, efforts have been expended to create reliable, cost-effective, small, and high-performance packages. Such requirements are, for example, reductions in electrical signal propagation delays, reductions in overall component area, and broader latitude in input/output (I/O) connection pad placement. In order to meet those requirements, a WLP (wafer level package) has been developed, wherein an array of I/O terminals is distributed over the active surface, rather than peripheral-leaded package. Such distribution of terminal may increase the number of I/O terminals and improves the electrical performance of the device. Further, the area occupied by the IC with interconnections when mounted on a printed circuit board is merely the size of the chip, rather than the size of a packaging lead-frame. Thus, the size of the WLP may be made very small. One such type may refer to chip-scale package (CSP).

Improvements in IC packages are driven by industry demands for increased thermal and electrical performance and decreased size and cost of manufacture. In the field of semiconductor devices, the device density is increased and the device dimension is reduced, continuously. The demand for the packaging or interconnecting techniques in such high density devices is also increased to fit the situation mentioned above. The formation of the solder bumps may be carried out by using a solder composite material. Flip-chip technology is well known in the art for electrically connecting a die to a mounting substrate such as a printed wiring board. The active surface of the die is subject to numerous electrical couplings that are usually brought to the edge of the chip. Electrical connections are deposited as terminals on the active surface of a flip-chip. The bumps include solders and/or plastics that make mechanical connections and electrical couplings to a substrate. The solder bumps after RDL have bump high around 50-100 um. The chip is inverted onto a mounting substrate with the bumps aligned to bonding pads on the mounting substrate, as shown in FIG. 1. If the bumps are solder bumps, the solder bumps on the flip-chip are soldered to the bonding pads on the substrate. Solder joints are relatively inexpensive, but exhibit increased electrical resistance as well as cracks and voids over time due to fatigue from thermo-mechanical stresses. Further, the solder is typically a tin-lead alloy and lead-based materials are becoming far less popular due to environmental concerns over disposing of toxic materials and leaching of toxic materials into ground water supplies.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

The conventional die is only covered by glass and other surfaces of the die are exposed. It is possible to crash the die by external force. The process is also complicated, therefore, the present invention provides a safer scheme to overcome the aforementioned problem and also provide the better device performance.

### SUMMARY OF THE INVENTION

An object of the present invention is to provide a semiconductor device package (chip assembly) that provides a low cost, high performance and high reliability package.

An interconnecting structure for a semiconductor die assembly comprises: a die having bonding pads on an active surface; a core attached the side wall (edge) of the die by adhesion material; an isolating base adhered on the active surface of the die by adhesion glue; a through silicon via (TSV) open from the back side of the die to expose the bonding pads; a build up layer coupled between the bonding pads to terminal metal pads by the through silicon via; solder balls melted on terminal pads, wherein the terminal pads located on the core and/or the die.

The build up layer includes a first dielectric layer, a re-distribution layer (RDL) and a second dielectric layer on the RDL and the first dielectric layer. RDL is formed by laminated copper foil with patterned etching, or by sputtered metal (Ti/Cu) and patterned E-plated Cu/Ni/Au. The material of the isolating base includes glass, crystal, ceramic, silicon, PI, BT, FR4, FR5, PCB, alloy, organic materials or metal. The material of the core includes PI, BT, FR4, FR5, silicon, glass, ceramic, crystal, PCB, EMC, silicone rubber or resin. Inter-connecting through holes are formed inside the core for coupling signals between on both sides of the die. The material of adhesion material includes elastic material.

An image sensor package structure, comprises an image sensor die having bonding pads and micro lens on an active surface; a core attached the side wall (edge) of the die by adhesion material; a transparent material adhered on the active surface of the die by adhesion glue; a through silicon via (TSV) opened from the back side of the die to expose the bonding pads; at least one RDL coupled to the TSV and conductive bumps connected to the RDL.

A semiconductor device package structure comprises at least one die having bonding pads on an active surface; a core attached the side wall (edge) of the die by adhesion material; an isolation base adhered on the active surface of the die by adhesion glue; a through silicon via (TSV) opened from the back side of the die to expose the bonding pads; at least one RDL coupled to the TSV and conductive bumps connected to the RDL.

A multi-chips package structure, comprising: a lower package includes a first die having first bonding pads on a first active surface; a first core (substrate) having inter-connecting through holes with contact pads on both side to attach the side wall (edge) of the first die by a first adhesion material; a first through silicon via (TSV) opened from the back side of the first die to expose the first bonding pads; a first RDL coupled to the first bonding pads and contact pads; and an upper package includes a second die having second bonding pads on a second active surface; a second core attached the side wall (edge) of the second die by a second adhesion material; a second through silicon via (TSV) opened from the back side of the second die to expose the second bonding pads; a second RDL coupled to the second bonding pads; an isolation based formed on the top of upper package; wherein the lower package and the upper package is coupled by interconnecting solder connected between the second RDL and upper contact of the lower package.

A multi-chips package structure, comprises a lower package includes a first die having first bonding pads on a first active surface; a first core having inter-connecting through holes with contact pads on both side to attach the side wall (edge) of the first die by a first adhesion material; a first through silicon via (TSV) opened from the back side of the first die to expose the first bonding pads; a first RDL coupled to the first TSV; and an upper package includes a second die having second bonding pads on a second active surface; a second core attached the side wall (edge) of the second die by a second adhesion material; a second through silicon via (TSV) opened from the back side of the second die to expose the second bonding pads; a second RDL coupled to the second bonding pads; wherein the lower package and the upper package is coupled by at least one isolation based formed there-between, thereby constructing face-to-face (from the active surface of die point of view) configuration; pluralities of CNC through holes penetrating from the first core to the second core, and coupling the first RDL to second RDL, and conductive metal fill into the CNC through holes.

### BRIEF DESCRIPTION OF THE DRAWINGS

FIG. 1 is cross-sectional views showing an image sensor chip assembly in accordance with embodiment of the present invention.

FIG. 2 illustrates a cross section view showing an image sensor chip assembly in accordance with embodiment of the present invention.

FIGS. 3a and 3b illustrate a cross section view showing semiconductor chip assembly in accordance with embodiment of the present invention.

FIG. 4 illustrates a cross section view showing side-by-side semiconductor chips assembly in accordance with embodiment of the present invention.

FIG. 5 illustrates a cross section view showing stacking semiconductor chip assembly in accordance with further embodiment of the present invention.

FIG. 6 illustrates a cross section view showing face-to-face semiconductor chip assembly in accordance with embodiment of the present invention.

FIGS. 7a and 7b illustrate a cross section view showing inter-connecting structure in accordance with embodiment of the present invention.

FIG. 8 illustrates a cross section view showing BUL in accordance with embodiment of the present invention.

### DETAILED DESCRIPTION OF A PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

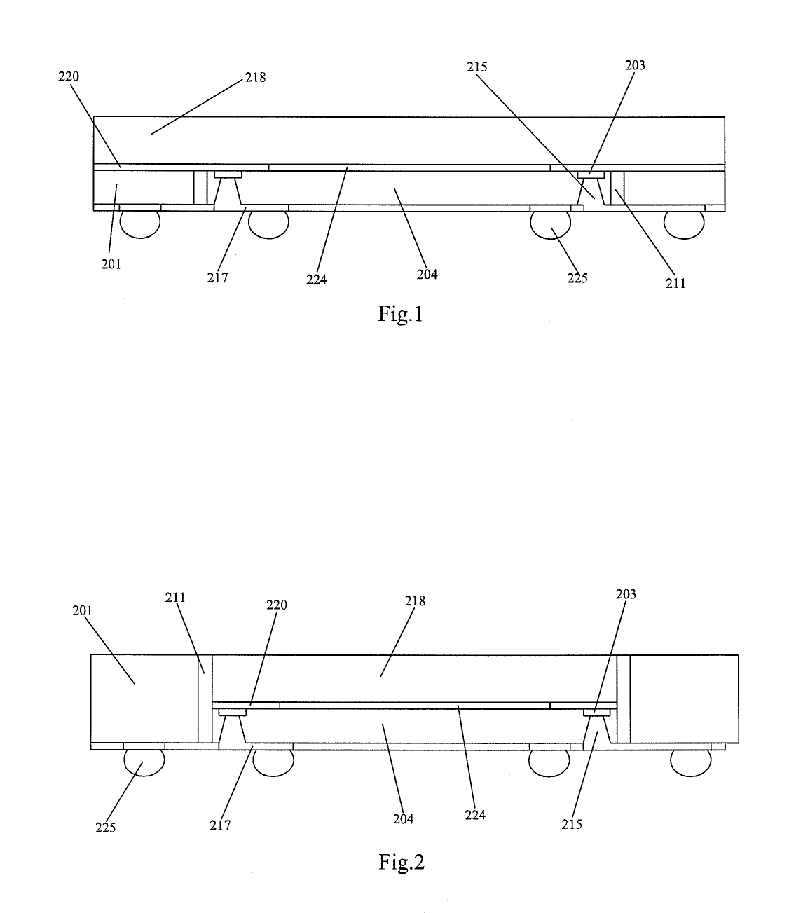

The present invention discloses a semiconductor device package structure. The present invention provide a semiconductor chip assembly which includes chip, conductive trace and metal inter-connecting as shown in FIG. 1.

FIG. 1 is cross-sectional view of a substrate (core) 201. The core 201 has a die receiving window 202 for receiving a die 204. The die is CMOS sensor for one embodiment. It could be a single or multi-layer substrate. The chip 204 is adhesion on the surface by an adhesive material 211. It could have the elastic properties to absorb the stress generated by thermal. The interconnecting structures 215 are coupled between the bonding pads 203 over the upper surface of chip 204 and the RDL 217 under the surface of the chip 204. Preferably, the interconnecting structures 215 are TSV (through silicon via). The pads 203 could be Al, Cu pads or other metal pads. The core 201 is formed adjacent to the die 204 for protection. It is noted that partial of the RDL 217 is exposed by the lower isolation base 216 for receiving the conductive balls 225. The conductive bumps 225 are coupled to the RDL 217. The isolation base (or mask) 216 with bump (ball) openings is formed under the chip 204. For example, the isolation base 216 is composed of epoxy/BT, preferably, it is BT base with fiber glass formed therein. The RDL 217 is formed by an electroplating, plating or etching method. The copper electroplating operation continues until the copper layer has the desired thickness. Conductive layers extend out of the area for receiving chip. It refers to fan-out scheme. The fan-out scheme has better thermal dissipation and larger pitch between balls for reducing the signal interference. A transparent material 218 is attached over the chip 204 by adhesive material 220, and the adhesive material exposes the micron lens area 222 of the chip 204, thereby generating a gap 224 between the micron lens area 222 and the transparent material 218.

FIG. 2 shows alternative embodiment of the present invention. Most of the structure is similar to the embodiment of above, except the dimension of the core 201. The height of the core 201 is substantially equal to the total thickness of the transparent material 218, adhesion material 203 and the chip 204. It means that the depth of die receiving window 202 is deeper.

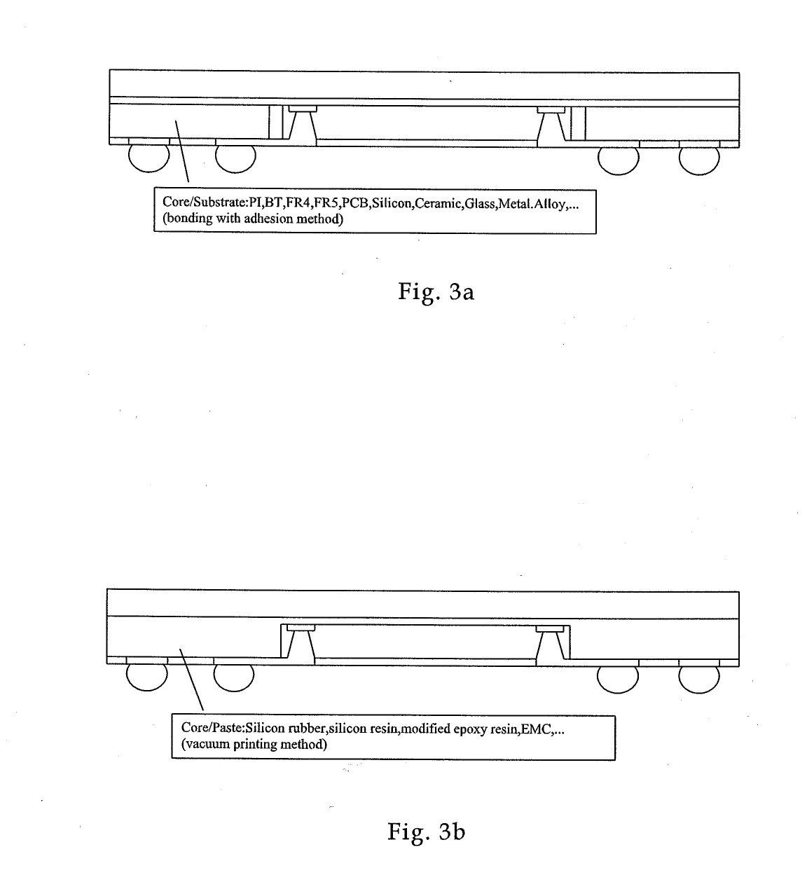

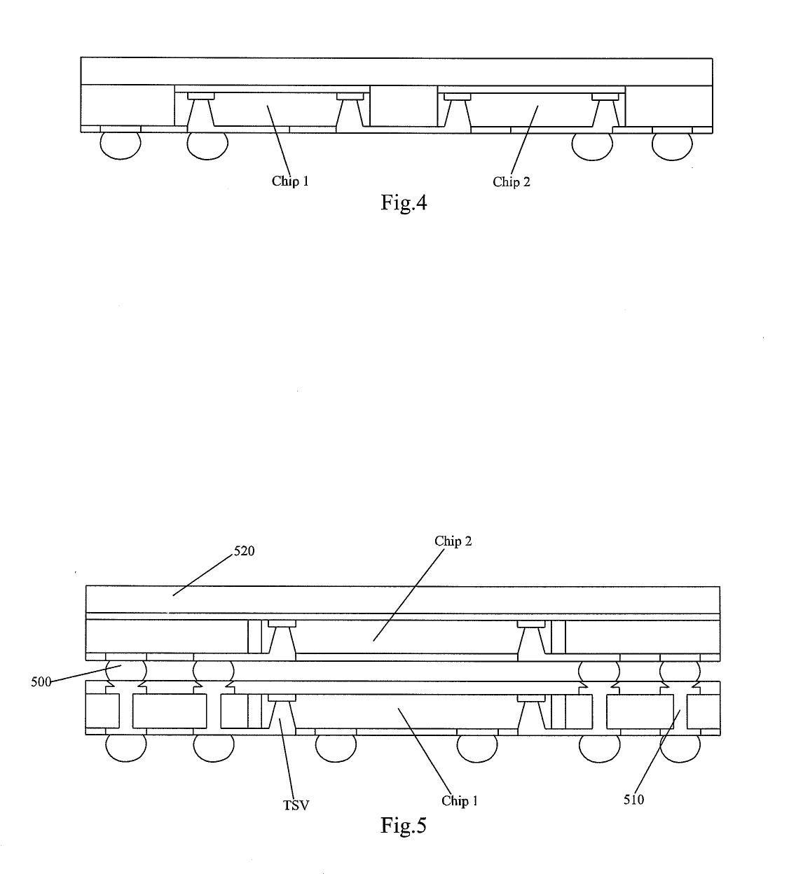

Please refer to FIGS. 3 and 4, they illustrate two types of the desired substrate material depending on the method selected. If the isolating base (or transparent) material is bonding with adhesion material on the core 201 as FIG. 3a, the core material will be PI, BT, FR4, FR5, PCB, Silicon, Ceramic, Glass, Metal, Alloy or the like. Alternatively, if the core is selected from Silicone rubber, silicone resin, modified epoxy resin, EMC or the like. It suits for (vacuum) printing method, as shown in FIG. 3b.

FIG. 4 shows another embodiment of the present invention. The device includes at least two chips embedded into the package structure to form the side-by-side scheme. Alternatively, stacking structure is also provided by connecting two units of the previously embodiments through inter-connecting solder 500 and interconnecting through holes 510 inside the core of the lower package as shown in FIG. 5. It may be noted that the inter-connecting solder 400 are connected between the lower contacts (or RDL) of the upper package and the upper contacts of the lower package. An isolation base 520 is formed over the upper surface of the upper package.

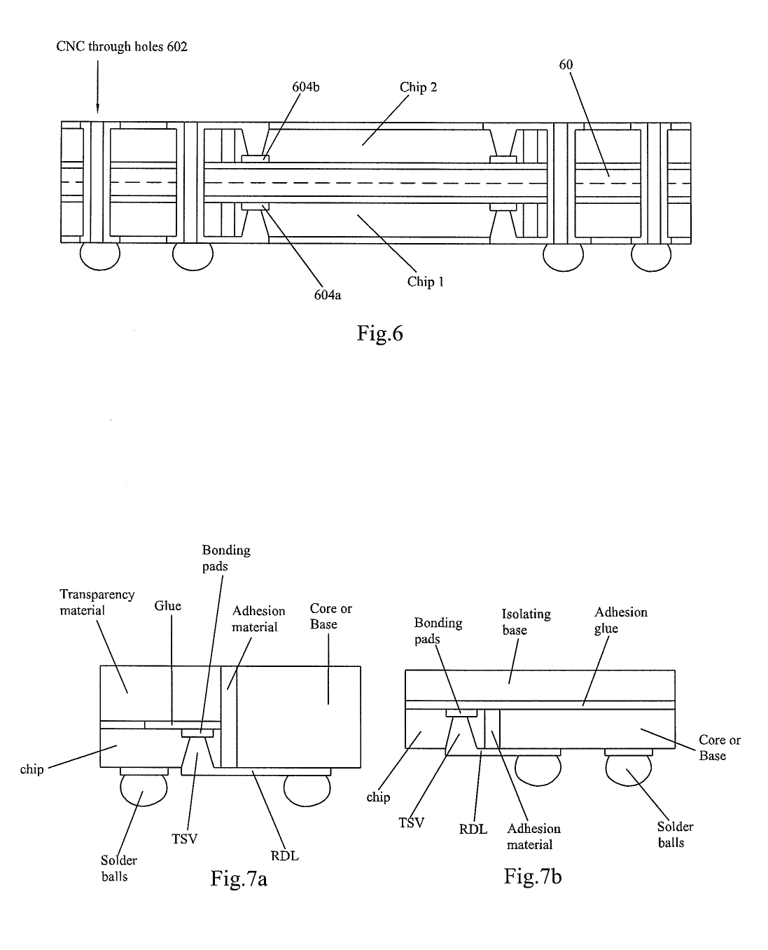

FIG. 6 illustrates the face-to-face scheme with CNC through hole having E-plating Cu therein. In the scheme, the upper package is stacked on the lower package by the isolation base 600. The isolation base 600 may be one unit and shared by the two packages, or constructed by two single isolation bases and the dual isolation base are adhesion with each other. Pluralities of CNC through holes 602 with plating Cu/Ni/Au are formed and penetrated from the top to bottom of the stacking structure. One aspects of the embodiment is that the active surfaces (the surface includes the bonding pads 604a, 604b) of both packages are face-to-face configuration.

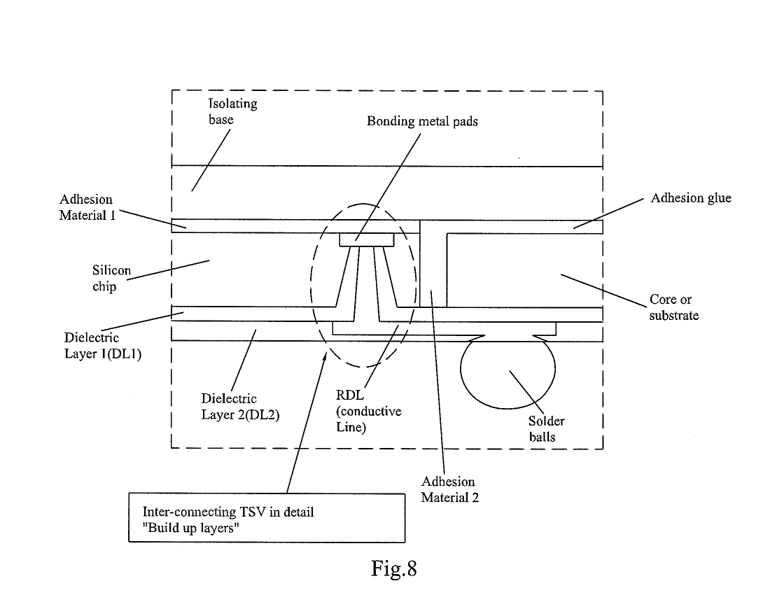

Please refer to FIG. 7a, the core or base having a die receiving window to receive and attach the chip by adhesion material. The transparent material is attached over the active surface of the chip through glue. The RDL is configured on the lower surface of the package and coupled between the solder balls and the TSV embedded inside the chip. As shown, the TSV is connected to the bonding pads covered by the glue. FIG. 7b illustrates another example of the present invention, the core or base having a die receiving window to receive and attach the chip by adhesion material. The isolation base is attached over the active surface of the chip and the core through adhesion glue. The adhesion glue is substantially covered entire surface of the chip and the core. In the last structure, the thickness of the core is substantially equal to the isolation base, glue and the chip. However, in the case, the thickness of the core is substantially equal to the one of the chip. The RDL is configured on the lower surface of the package and coupled between the solder balls and the TSV embedded inside the chip. The TSV is connected to the bonding pads covered by the glue. The case of FIG. 7a is suitable for image sensor, and the later (FIG. 7b) is suitable to other devices. FIG. 8 illustrates the BUL structure having RDL under the lower surface of each embodiment. The build up layer includes a first dielectric layer (DL1), a re-distribution layer (RDL) and a second dielectric layer (DL2) on the RDL and the first dielectric layer.

Advantages: the package size is independent to the chip size and may keep the same ball pitch with the one of the chip. It offers better reliability in via inter-connecting. The chip's active surface is protected during process and it provides better electrical isolation from top surface. Thinner chip is better for reliability and it provides easy processes to form the thinner chips. Side-by-side and stacking package maybe provided easily, it is also easy to fan-out the terminal pins.

In order to achieve the scheme, the essential conditions under the bonding pads include: no active circuitry permitted under the bonding pads, it needs the insulating layer structure and insulating layer materials to isolate the RDL to contact with silicon itself due to silicon itself is semi-conductor. The pitch of bonding pads should be considered and alignment key is necessary from upper surface to lower surface.

The method of forming a semiconductor die assembly comprises: bonding an isolating base having adhesion material on the active surface side of a wafer and curing the adhesion material that is mounted on a tape and lapping the back side of the wafer to desired thickness, it maybe from 25 um to 100 um, followed by dicing the wafer with isolating base together, then, picking and placing the die with the isolating base on a die placement tools with back side (Via Holes) stuck on the die placement tools by pattern glues. Next, core (or substrate) is placed onto the die placement tools, adhesion materials is filled into gap between the edge of the die and side wall of the core, thereby forming a panel; the adhesive material is cured after filling the adhesive material, followed by separating the panel from the die placement tools. The next step is to form TSV within the die. Seed metal is sputtered and PR is coated to define a trace pattern, followed by forming RDL to couple the TSV and forming solder balls.

The method further comprises a step of drilling the wafer by laser drill, dry etching or wet etching (with pattern) through back side in order to form via contact after lapping the wafer. Alternatively, it could be done after curing the adhesive material. It also further comprises a step of curing the adhesive material after filling the adhesive material.

Typically, under bump metallurgy (UBM) is formed before the formation of the ball as the barrier and adhesion for preventing the issue between the ball and the ball pad.

Although preferred embodiments of the present invention have been described, it will be understood by those skilled in the art that the present invention should not be limited to the described preferred embodiment. Rather, various changes and modifications can be made within the spirit and scope of the present invention, as defined by the following Claims.

What is claimed is:

1. An interconnecting structure for a semiconductor die assembly, comprising:
a die having bonding pads on an active surface;
a core attached the side wall (edge) of said die by adhesion material;
an isolating base adhered on said active surface of said die by adhesion glue;
a through silicon via (TSV) open from the back side of said die to expose said bonding pads;
a build up layer coupled between said bonding pads to terminal metal pads by said through silicon via.

2. The structure of claim 1, further comprising solder balls melted on terminal pads, wherein said terminal pads located on said core and/or said die.

3. The structure of claim 1, wherein said build up layer includes a first dielectric layer, a re-distribution layer (RDL) and a second dielectric layer on said RDL and said first dielectric layer.

4. The structure of claim 3, wherein said RDL is formed by laminated copper foil or sputtered metal (Ti/Cu) and patterned E-plated Cu/Ni/Au.

5. The structure of claim 1, wherein the material of said isolating base includes glass, crystal, ceramic, silicon, PI, BT, FR4, FR5, PCB, alloy, organic materials or metal.

6. The structure of claim 1, wherein the material of said core includes PI, BT, FR4, FR5, silicon, glass, ceramic, crystal, PCB, EMC, silicone rubber or resin.

7. The structure of claim 1, further comprising inter-connecting through holes formed inside said core for coupling signals between on both sides of said die.

8. The structure of claim 1, wherein the materials of adhesion material includes elastic material.

9. An image sensor package structure, comprising:
an image sensor die having bonding pads on an active surface;
a core attached the side wall (edge) of said die by adhesion material;
a transparent material adhered on said active surface of said die by adhesion glue;
a through silicon via (TSV) opened from the back side of said die to expose said bonding pads;
at least one RDL coupled to said TSV and conductive bumps connected to said RDL.

10. The structure of claim 9, wherein the material of said core includes PI, BT, FR4, FR5, silicon, glass, ceramic, crystal, PCB, EMC, silicone rubber or resin.

11. The structure of claim 9, wherein the materials of adhesion material includes elastic material.

12. A semiconductor package structure, comprising:
at least one die having bonding pads on an active surface;
a core attached the side wall (edge) of said die by adhesion material;
an isolation base adhered on said active surface of said die by adhesion glue;
a through silicon via (TSV) opened from the back side of said die to expose said bonding pads;
at least one RDL coupled to said TSV and conductive bumps connected to said RDL.

13. The structure of claim 12, wherein the material of said core includes PI, BT, FR4, FR5, silicon, glass, ceramic, crystal, PCB, EMC, silicone rubber or resin.

14. The structure of claim 12, wherein the materials of adhesion material includes elastic material.

15. The structure of claim 12, wherein the material of said isolating base includes glass, crystal, ceramic, silicon, PI, BT, FR4, FR5, PCB, alloy, organic materials or metal.

16. The structure of claim 12, further comprising a second die within said package structure.

17. A multi-chips package structure, comprising:
a lower package includes a first die having first bonding pads on a first active surface; a first core having inter-connecting through holes with contact pads on both side to attach the side wall (edge) of said first die by a first adhesion material; a first through silicon via (TSV) opened from the back side of said first die to expose said first bonding pads; a first RDL coupled to said first bonding pads and said contact pads of said first core; and
an upper package includes a second die having second bonding pads on a second active surface; a second core attached the side wall (edge) of said second die by a second adhesion material; a second through silicon via (TSV) opened from the back side of said second die to expose said second bonding pads; a second RDL coupled to said second bonding pads; an isolation based formed on said upper package; wherein said lower package and said upper package is coupled by interconnecting solder connected between said second RDL and upper contact of said lower package.

18. The structure of claim 17, wherein the material of said first and second core includes PI, BT, FR4, FR5, silicon, glass, ceramic, crystal, PCB, EMC, silicone rubber or resin.

19. The structure of claim 17, wherein the material of said isolating base includes glass, crystal, ceramic, silicon, PI, BT, FR4, FR5, PCB, alloy, organic materials or metal.

20. A multi-chips package structure, comprising:
a lower package includes a first die having first bonding pads on a first active surface; a first core having inter-connecting through holes with contact pads on both side to attach the side wall (edge) of said first die by a first adhesion material; a first through silicon via (TSV) opened from the back side of said first die to expose said first bonding pads; a first RDL coupled to said first bonding pads and said contact pads of said first core; and
an upper package includes a second die having second bonding pads on a second active surface; a second core attached the side wall (edge) of said second die by a second adhesion material; a second through silicon via (TSV) opened from the back side of said second die to expose said second bonding pads; a second RDL coupled to said second bonding pads; wherein said lower package and said upper package is coupled by at least one isolation based formed there-between, thereby constructing face-to-face configuration; pluralities of CNC through holes penetrating from said first core to said second core and coupling said first RDL and said second RDL.

21. The structure of claim 20, wherein the material of said first and second core includes PI, BT, FR4, FR5, silicon, glass, ceramic, crystal, PCB, EMC, silicone rubber or resin.

22. The structure of claim 20, wherein the material of said isolating base includes glass, crystal, ceramic, silicon, PI, BT, FR4, FR5, PCB, alloy, organic materials or metal.

23. The structure of claim 20, wherein said pluralities of CNC through holes includes copper.

24. A method of forming a semiconductor die assembly, comprising:
bonding an isolating base on the active surface of a wafer and curing said wafer that is mounted on a tape;
lapping the back side of said wafer to desired thickness;
dicing said wafer with isolating base;
picking and placing said die with said isolating base on a die placement tools with back side (Via Holes) stuck on said die placement tools by pattern glues;
placing core (or substrate) onto said die placement tools;
filling adhesion materials into gap between the edge of said die and side wall of said core, thereby forming a panel;
separating said panel from said die placement tools;
forming a TSV within said die;
sputtering seed metal, coating PR to define a trace pattern;
forming RDL to couple said TSV;
forming solder balls.

25. The method of claim 24, wherein said RDL is formed by laminated copper foil, sputtered metal or E-plated Cu/Ni/Au.

26. The method of claim 24, wherein the material of said core includes PI, BT, FR4, FR5, silicon, glass, ceramic, crystal, PCB, EMC, silicone rubber or resin.

27. The method structure of claim 24, wherein the material of said isolating base includes glass, crystal, ceramic, silicon, PI, BT, FR4, FR5, PCB, alloy or metal.

28. The method structure of claim 24, further comprising a step of drilling said wafer by laser drill, dry etching or wet etching (with pattern) through back side in order to form via contact after lapping said wafer.

29. The method structure of claim 24, further comprising a step of curing said adhesive material after filling said adhesive material.

30. The method structure of claim 29, further comprising a step of drilling said wafer by laser drill, dry etching or wet etching (with pattern) through back side in order to form via contact after curing said adhesive material.
